(19) United States
(12) Patent Application Publication
(10) Pub. No.: US 2024/0099041 A1
(43) Pub. Date: Mar. 21, 2024

(54) Light-Emitting Element

(71) Applicant: SHARP KABUSHIKI KAISHA, Sakai City, Osaka (JP)

(72) Inventor: YOSHIHIRO UETA, Sakai City, Osaka (JP)

(21) Appl. No.: 17/769,573

(22) PCT Filed: Oct. 29, 2019
(86) PCT No.: PCT/JP2019/042283

§ 371 Date: Apr. 15, 2022

(51) Int. Cl. H10K 50/115; H10K 50/16; H10K 77/10

(52) U.S. Cl. CPC H10K 50/115; H10K 50/16; H10K 77/10

(57) ABSTRACT

A light-emitting element includes: an anode, a light-emitting layer, a layer capable of transporting electrons, and a cathode, all of which are provided in a stated order; and an insulator layer provided in contact with, and at least partially between, the layer capable of transporting the electrons and the cathode, the insulator layer having a relative permittivity of 2 or higher and 50 or lower. The insulator layer includes a plurality of insulator layers shaped into islands and spaced apart from one another. The insulator layers are distributed non-uniformly in plan view.

### TECHNICAL FIELD

The present disclosure relates to a light-emitting element.

### BACKGROUND ART

When carriers (electrons and holes) are injected into such a self-luminous light-emitting element as an organic light-emitting diode (OLED), a quantum-dot light-emitting diode (QLED), and an inorganic light-emitting diode, the energy levels of carrier injection layers for the respective electrons and holes have to be appropriately selected in order to efficiently inject the electrons and the holes into a light-emitting layer.

### CITATION LIST

### Patent Literature

[Patent Document 1] Japanese Unexamined Patent Application Publication No. 2005-123094

### SUMMARY OF INVENTION

### Technical Problems

An energy level of the light-emitting layer is determined, depending on a material of the light-emitting layer. In a case of the QLED, for example, the material of the quantum dots cannot be selected freely. This is because the holes and the electrons are efficiently confined in the quantum dots, and recombined together to generate an exciton and emit light. For example, of a currently used quantum-dot layer, the electron affinity in injecting the electrons is close to 3 eV or below. In order to inject the electrons into such a quantum-dot layer, the layer capable of transporting the electrons has to be an electron-transport layer or an electron-injection layer with a low electron affinity, and the cathode to be used has to have a small work function.

A typical electron-transporting material to be used for forming a layer capable of transporting the electrons is formed in ionic bonding, and the bonding strength among the constituent elements of the material is relatively high. However, if the layer capable of transporting the electrons is deposited by, for example, sputtering, the layer capable of transporting the electrons is, for example, exposed to ion bombardment. Hence, on a surface of the layer capable of transporting the electrons, a great deep-level defect is formed. Furthermore, in deposition by application of nanoparticles, the rate of the surface area of the layer capable of transporting the electrons increases thanks to the size effect. Because of a lattice defect and a deviation from stoichiometry, for example, a great deep-level defect is formed on the surface of the layer. When the deep-level defect is formed on the surface of the layer capable of transporting the electrons, a Fermi level of the cathode is pinned to the deep-level defect, and the Fermi level of the cathode becomes deep. As a result, formed between the layer capable of transporting the electrons and the cathode is an electron injection barrier significantly higher than expected from the properties of materials of the layer and the cathode. The barrier blocks injection of the electrons.

Note that, for example, Patent Document 1 discloses techniques. One of the techniques is to form an organic-metal-complex-containing layer on a layer (a low-resistance electron-transport layer): adjacent to a light-emitting layer made of an organic compound; and containing a mixture of an electron-donating metal dopant and an organic substance. Vapor-deposited on the organic-metal-complex-containing layer is a heat-reducing metal formed as the cathode and capable of reducing, in a vacuum, metal ions in the organic-metal-complex-containing layer into metal. Hence, the organic-metal-complex-containing layer undergoes redox reaction. Another technique is to vapor-deposit the heat-reducing metal on the organic-metal-complex-containing layer so that the organic-metal-complex-containing layer undergoes redox reaction. After that, the cathode is formed. Use of either technique reduces an energy barrier (i.e. an electron-injection barrier) that is a problem when the electrons are injected from the cathode into the low-resistance electron-transport layer.

However, the organic-metal-complex-containing layer and a reduction-induced layer, which is produced by the redox reaction on an interface between the organic-metal-complex-containing layer and the cathode, are both electrically conductive. Moreover, the reduction action on the reduction-induced layer causes a defect on the surface of the organic-metal-complex-containing layer. Hence, in Patent Document 1, a deep-level defect is formed on the surface of the organic-metal-complex-containing layer, and a Fermi level of the cathode is pinned to the deep-level defect (a surface level) of the organic-metal-complex-containing layer. However, Patent Document 1 is utterly silent as to the above pinning. In a light-emitting element of Patent Document 1, the Fermi level of the cathode becomes deep because of the pinning, and, as a result, the work function of the cathode becomes deep. Hence, formed between the low-resistance electron-transport layer and the cathode is an electron injection barrier significantly higher than expected from the properties of the materials of the layer and the cathode. The barrier blocks injection of the electrons.

An aspect of the present disclosure is conceived in view of the above problems, and is intended to provide a light-emitting element capable of injecting electrons into a light-emitting layer more efficiently than a conventional light-emitting element.

### Solution to Problems

In order to solve the above problems, a light-emitting element according to an aspect of the present disclosure includes: an anode, a light-emitting layer, a layer capable of transporting electrons, and a cathode, all of which are provided in a stated order; and an insulator layer provided in contact with, and at least partially between, the layer capable of transporting the electrons and the cathode. The insulator layer has a relative permittivity of 2 or higher and 50 or lower.

### Advantageous Effects of Invention

According to an aspect of the present disclosure, the above insulator layer is provided at least partially between the light-emitting layer and the cathode, and in contact with the cathode and the layer capable of transporting the electrons. Such a feature makes it possible to reduce a move of charges between the cathode and the surface level of the layer capable of transporting the electrons, and keep the Fermi level of the entire cathode from being pinned to a great deep-level defect. Hence, an aspect of the present disclosure can reduce the risk that the entire cathode is affected by an influence, on the Fermi level, of the surface level of the layer capable of transporting the electrons, and can join the cathode and the layer capable of transporting the electrons through the insulating layer with an original work function for the cathode. Hence, an aspect of the present disclosure can reduce at least a portion of an electron-injection barrier between the cathode and the layer capable of transporting the electrons, contributing to more efficient injection of the electrons than a conventional technique.

### BRIEF DESCRIPTION OF DRAWINGS

FIG. 1 is a cross-sectional view of an exemplary schematic configuration of a light-emitting device according to a first embodiment.

FIG. 2 is an energy band diagram illustrating an electron-injection barrier between a cathode and a layer capable of transporting electrons in the light-emitting element according to the first embodiment.

FIG. 3 is an energy band diagram illustrating an electron-injection barrier between a cathode and a layer capable of transporting electrons in a comparative light-emitting element.

FIG. 4 is a cross-sectional view of an exemplary schematic configuration of the light-emitting device according to a second embodiment.

FIG. 5 is a perspective view of a schematic configuration of an essential part in the light-emitting device according to the second embodiment.

FIG. 6 is a perspective view of a schematic configuration of an essential part in the light-emitting device according to a third embodiment.

FIG. 7 is a perspective view of a schematic configuration of an essential part in the light-emitting device according to a fourth embodiment.

FIG. 8 is a perspective view of a schematic configuration of an essential part in the light-emitting device according to a fifth embodiment.

### DESCRIPTION OF EMBODIMENTS

Described below is an embodiment of the present disclosure. In the description below, a “layer below” means that the layer is formed in a previous process before a comparative layer. A “layer above” means that the layer is formed in a successive process after a comparative layer.

<Schematic Configuration of Light-Emitting Element>

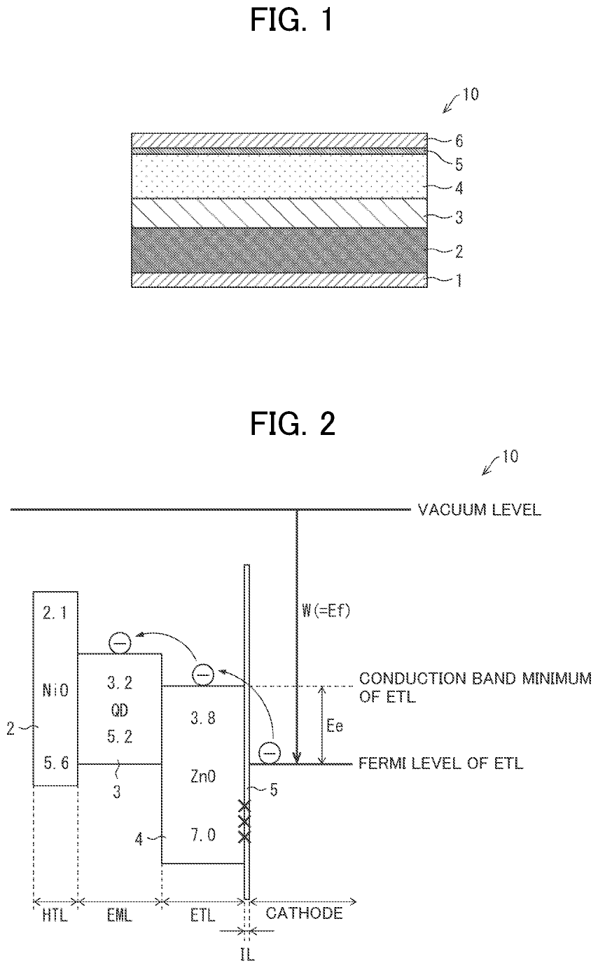

FIG. 1 is a cross-sectional view of an exemplary schematic configuration of a light-emitting device 10 according to this embodiment when the light-emitting element 10 is cut in the normal direction (i.e. when the light-emitting element 10 is cut in the stacking direction of the light-emitting element 10).

As illustrated in FIG. 1, the light-emitting element 10 includes: an anode 1; a cathode 6; and a light-emitting layer 3 (hereinafter referred to as an “EML 3”) provided between the anode 1 and the cathode 6. Provided between the cathode 6 and the EML 3 is an insulator layer 5 (hereinafter referred to as an “IL 5”) in contact with the cathode 6. Moreover, provided between the IL 5 and the EML 3 is a layer 4 capable of transporting electrons (hereinafter referred to as an “ETL 4”) in contact with the IL 5. Note that, a layer 2 capable of transporting holes (hereinafter referred to as an “HTL 2”) may be provided between the anode 1 and the EML 3. The HTL 2 may be omitted.

FIG. 1 shows an exemplary case where the light-emitting element 10 includes the anode 1, the HTL 2, the EML 3, the ETL4, the IL5, and the cathode 6, all of which are provided in the stated order from below. However, as described above, the configuration of the light-emitting element 10 shall not be limited to the above configuration.

Moreover, the above layers included in the light-emitting element 10 may be stacked in the reverse order. For example, the light-emitting element 10 may include the anode 1, the HTL 2, the EML 3, the ETL 4, the IL5, and the cathode 6 in the stated order from above.

The anode 1, made of a conductive material, injects holes in a layer between the anode 1 and the cathode 6. The cathode 6, made of a conductive material, injects electrons in a layer between the cathode 6 and the anode 1.

Examples of the conductive material to be used for the anode 1 include: a known metal to be typically used for an anode such as aluminum (Al), silver (Ag), and magnesium (Mg); an alloy of these metals; an inorganic oxide such as indium tin oxide (ITO), and indium gallium zinc oxide (InGaZnOx); and a conductive compound made of these inorganic oxides doped with an impurity. These conductive materials may be used either alone, or in appropriate combination of two or more of the materials.

Examples of the conductive material to be used for the cathode 6 include: a known metal to be typically used for a cathode such as Al, Ag, and Mg; and an alloy of these metals. These conductive materials may be used either alone, or in appropriate combination of two or more of the metals. Moreover, the above alloy may further contain lithium (Li).

Note that, of the anode 1 and the cathode 6, the electrode toward the light releasing face has to be transparent. Meanwhile, the electrode across from the light releasing face may be either transparent or opaque. Hence, at least one of the anode 1 or the cathode 6 is made of a light-transparent material. One of the anode 1 or the cathode 6 may be formed of a light-reflective material. If the light-emitting element 10 in FIG. 1 is a top-emission light-emitting element, the cathode 6 provided above is formed of a light-transparent material, and the anode 1 provided below is formed of a light-reflective material. If the light-emitting element 10 in FIG. 1 is a bottom-emission light-emitting element, the cathode 6 provided above is formed of a light-reflective material, and the anode 1 provided below is formed of a light-transparent material.

The anode 1 and the cathode 6 can be formed by conventionally known various techniques to form an anode and a cathode, such as, for example, sputtering, vacuum vapor deposition, chemical vapor deposition (CVD), plasma CVD, and printing.

The HTL 2 may be either a hole-transport layer or a hole-injection layer. The hole-transport layer transports the holes from the anode 1 to the EML 3. The hole-injection layer encourages injection of the holes from the anode 1 to the EML 3. Note that the hole-transport layer may also act as the hole-injection layer, and the anode 1 may also act as the hole-injection layer. Hence, between the anode 1 and the EML 3, the light-emitting element 10 may include, as the HTL2, the hole-injection layer and the hole-transport layer in the stated order from toward the anode 1. The light-emitting element 10 may include the hole-transport layer alone.

The HTL 2 may be formed of a known hole-transporting material. The HTL 2 may contain, as the hole-transporting material, for example: nickel oxide (NiO), copper aluminate (CuAlO₂), poly(3,4-ethylenedioxythiophene)-poly(4-styrene sulfonate) (PEDOT:PSS), polyvinyl carbazole (PVK), and poly[(9,9-dioctylfluorenyl-2,7-diyl)-co-(4,4′-(N-(4-sec-butylphenyl)diphenylamine)] (TFB). These hole-transporting materials may be used either alone, or in appropriate combination of two or more of the materials. Moreover, the hole-transporting materials may be nanoparticles.

The ETL 4 may be either an electron-transport layer or an electron-injection layer. The electron-transport layer transports the electrons from the cathode 6 to the EML 3. The electron-injection layer encourages injection of the electrons from the cathode 6 to the EML 3. Note that the electron-transport layer may also act as an electron-injection layer. Hence, between the cathode 6 and the EML 3, the light-emitting element 10 may include, as the ETL 4, the electron-injection layer and the electron-transport layer in the stated order from toward the cathode 6. The light-emitting element 10 may include the electron-transport layer alone. That is, the light-emitting element 10 may include: the IL 5 provided, in contact with the cathode 6, between the cathode 6 and the EML 3; and either the electron-injection layer or the electron-transport layer, in contact with the IL 5, between the IL 5 and the EML 3. As can be seen, the IL 5 has one of principal planes necessarily in contact with the cathode. If the electron-transport layer alone is provided as the EML 3, the IL 5 has another one of the principal planes in contact with the electron-transport layer. If the electron-injection layer and the electron-transport layer are provided as the EML 3, the IL 5 has the other one of the principal planes in contact with the electron-injection layer.

The ETL 4 may be formed of a known electron-transporting material. The ETL 4 may contain, as the electron-transporting material, for example, a metal oxide, a II-VI semiconductor compound, a III-V semiconductor compound, and a IV-IV semiconductor compound. Examples of the above metal oxide include: molybdenum trioxide (MoO₃); chromium oxide (Cr₂O₃), nickel oxide (NiO), tungsten trioxide (WO₃), indium tin oxide (ITO), indium gallium zinc oxide (InGaZnOx), gallium oxide (Ga₂O₃), and indium oxide (In₂O₃). Examples of the II-VI semiconductor compound include: indium-doped zinc oxide (IZO); aluminum-doped zinc oxide (ZAO); zinc oxide (ZnO); magnesium oxide (MgO); zinc magnesium oxide (ZnMgO); zinc sulfide (ZnS); zinc selenide (ZnSe); zinc selenide sulfide (ZnSSe); magnesium sulfide (MgS); magnesium selenide (MgSe); and magnesium selenide sulfide (MgSSe). Examples of the II-V semiconductor compound include: aluminium arsenide (AlAs); gallium arsenide (GaAs); indium arsenide (InAs); AlGaInAs that is a mixed crystal of the arsenides; aluminum nitride (AlN); gallium nitride (GaN); indium nitride (InN); AlGaInN that is a mixed crystal of these nitrides; gallium phosphide (GaP); and AlInGaP. Examples of the IV-IV semiconductor compound include semiconductors made of different elements such as, silicon-germanium (SiGe); and silicon carbide (SiC). These electron-transporting materials may be used either alone, or in appropriate combination of two or more of the materials.

Note that the thickness of the HTL 2 and the ETL 4 does not have to be limited to a particular thickness as long as the HTL 2 and the ETL 4 are respectively and sufficiently capable of transporting the holes and the electrons. The HTL 2 and the ETL 4 may be respectively as thick as a layer capable of transporting the holes and a layer capable of transporting the electrons in a conventionally known light-emitting element.

These HTL 2 and ETL 4 are formed by conventionally known various techniques for forming a layer capable of transporting holes and a layer capable of transporting electrons. Examples of such techniques include sputtering, application of nanoparticles, and application of a precursor.

As described above, the IL 5 is provided in contact with, and between, the IL 5 and the cathode 6.

The IL 5 is an insulator layer having a relative permittivity (k) of 2 or higher and 50 or lower. The IL 5 may be an insulator made of, for example, aluminum oxide (Al₂O₃); silicon oxide (SiO₂); silicon nitride (SiN); silicon oxide nitride (SiON); aluminum oxide nitride (AlON); and titanium oxide (TIO₂). Note that, typically, the relative permittivity (k) of the above exemplary insulators is approximately: 6 to 10 for Al₂O₃; 3.5 to 4 for SiO₂; 7 for SiN; 7 to 8 for SiON; 9 for AlON; and 10 to 190 for TiO₂. Note that, as seen in the case of an insulator such as TiO₂, whose relative permittivity (k) significantly varies depending on an oxidation state, the insulator to be selectively used is in an oxidation state within a range of 2≤k≤50.

These insulators may be used either alone, or in appropriate combination of two or more of the insulators. Hence, the IL 5 may contain, for example, at least one kind of insulator selected from a group of Al₂O₃, SiO₂, SiN, SiON, AlON, and TiO₂ within a range of 2≤k≤50. Note that the insulator to be used for the IL 5 may be a typical one to be used for electronic devices as long as the relative permittivity (k) is within a range of 2≤k≤50. The insulator may be, for example, such a resin as polyimide (k=3.5). Examples of the insulators to be typically used for electronic devices include: a glass-epoxy multilayer stack (k=4.5 to 5.2); and dimethyl silicone resin (k=3 to 4).

In this embodiment, the IL 5 whose relative permittivity is 2 or higher and 50 or lower is provided in contact with, and between, the ETL 4 and the cathode 6. Such a feature makes it possible to ensure insulating properties of the IL 5, reduce a move of charges between the cathode 6 and the surface level (the deep-level defect) of the ETL 4, and keep the Fermi level of the cathode 6 from being pinned to the deep surface level of the ETL 4. Note that the above advantageous effects will be described later.

The IL 5 has a thickness of preferably 0.1 to 2 nm. The IL 5 having a thickness of 0.1 nm or more is provided between the ETL 4 and the cathode 6, making it possible to keep charges from moving from the deep-level defect of the ETL 4 (i.e. the electron-transport layer or the electron-injection layer) to the cathode 6. Note that if the IL 5 is thicker than 2 nm, a decrease is observed of a tunneling probability of the electrons moving from the cathode 6 to the ETL 6 by an external electric field. Hence, the IL 5 acts as a resistance element. As can be seen, the IL 5 is set to have a thickness of 0.1 to 2 nm. Such a feature makes it possible to keep charges from moving from the deep-level defect of the ETL 4 (i.e. the electron-transport layer or the electron-injection layer) to the cathode 6, and to keep the Fermi level of the cathode 6 from being pinned. In addition, the feature can reduce the risk that the IL 5 acts as a resistance element, contributing to efficient conduction of the electrons by tunneling.

Note that, in this embodiment, the ETL 4 and the cathode 6 are joined together by Schottky junction through the thin IL 5 as described above. The Schottky junction quickly releases the charges accumulated in a depletion layer, such that the light-emitting element 10 according to this embodiment excels in high speed operation.

Moreover, the IL 5 has a bandgap of preferably 5 eV or higher, and, more preferably 8 eV or higher. If the bandgap of the IL 5 is 5 eV or higher, no free carriers by thermal excitation are observed under an operation condition of the light-emitting element 10 (100° C. or below). Hence, the IL 5 can maintain its insulation properties. Moreover, if the bandgap of the IL 5 is 8 eV or higher, the wide bandgap contributes to more effective reduction of the move of charges from the deep-level defect on the surface of the ETL4 (the electron-transport layer or the electron-injection layer). Note that, if the bandgap of the IL 5 exceeds 10 eV, the atoms constituting the material of the IL 5 bond together tightly, making it difficult for the IL 5 to be deposited. Hence, the IL 5 has a bandgap of preferably 10 eV or lower. In such a case, the IL 5 can be easily deposited (formed).

Note that the IL 5 can be formed by conventionally known various techniques for forming an insulator layer. Examples of such techniques include sputtering, vapor-deposition, or application.

The EML 3, which contains a light-emitting material, emits light by recombination of the electrons transported from the cathode 6 and the holes transported from the anode 1.

As the light-emitting material, the EML 3 may contain, for example, quantum dots on nanoscale (semiconductor nanoparticles). The quantum dots may be known quantum dots. For example, the quantum dots may contain at least one kind of semiconductor material made of at least one kind of element selected from a group of: cadmium (Cd); sulfur (S); tellurium (Te); selenium (Se); zinc (Zn); indium (In); nitrogen (N); phosphorus (P); arsenic (As); antimony (Sb); aluminum (Al); gallium (Ga); lead (Pb); silicon (Si); germanium (Ge); and magnesium (Mg). Moreover, the above quantum dots may be of a two-component core type, a three-component core type, a four-component core type, a core/shell type, or a core/multishell type. Moreover, the above quantum dots may contain nanoparticles of at least doped one of the above elements. The quantum dots may have a composition gradient structure.

The particle size of the quantum dots may be a conventional particle size. The particle size of the cores of the quantum dots is, for example, 1 to 30 nm, and the outermost particle size of the quantum dots including the shells is, for example, 1 to 50 nm. Moreover, in the light-emitting element 10, each of the quantum dots includes, for example, 1 to 20 overlapping layers. The thickness of the EML 3 is any given thickness as long as the EML 3 is capable of recombining the electrons and the holes to emit light. For example, the thickness may be approximately 1 to 200 nm. Note that, preferably, the thickness of the EML 3 is several times as thick as the outermost particle size of the quantum dots.

Note that this embodiment shall not be limited to the above examples. As a light-emitting material, the EML 3 may include, instead of the quantum dots, organic light-emitting materials emitting lights in different colors.

If the light-emitting element 10 is a QLED including quantum dots as a light-emitting material as described above, the holes and the electrons recombine together in the EML 3 by a drive current between the anode 1 and the cathode 6, which forms an exciton. While the exciton transforms from the conduction band level to the valence band level of the quantum dots, light (fluorescence) is released.

If the light-emitting element 10 is an OLED including an organic light-emitting material as a light-emitting material, the holes and the electrons recombine together in the EML 3 by a drive current between the anode 1 and the cathode 6, which forms an exciton. While the exciton transforms to the ground state, light is released.

Moreover, the light-emitting element 10 may be a light-emitting element (e.g. an inorganic light-emitting diode) other than an OLED and a QLED.

At least one light-emitting element 10 (e.g. two or more light-emitting devices 10) may be included in a light-emitting device such as a lighting device and a display device to act as a light source of these light-emitting devices.

Moreover, the light-emitting element 10 may include a not-shown substrate. Either the anode 1 or the cathode 6 may be provided on the not-shown substrate. Note that the substrate may be, for example, a glass substrate, or a flexible substrate such as a resin substrate. Moreover, if the light-emitting element 10 is a part of a light-emitting device such as, for example, a display device, the substrate to be used is that of the light-emitting device. Hence, the substrate may be, for example, an array substrate on which a plurality of thin-film transistors are formed.

### Advantageous Effects

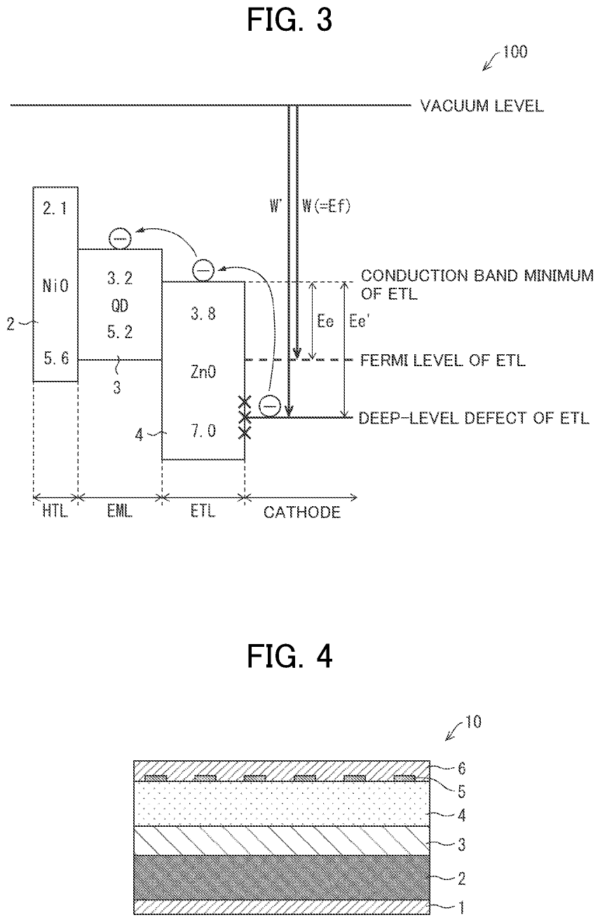

Described next in detail are advantageous effects achieved by the IL 5, with reference to FIGS. 2 and 3.

FIG. 2 is an energy band diagram illustrating an electron-injection barrier Ee between the cathode 6 and the ETL 4 in the light-emitting element 10 according to this embodiment. Whereas, FIG. 3 is an energy band diagram illustrating an electron-injection barrier Ee′ between the cathode 6 and the ETL 4 in a light-emitting element 100 for a comparative purpose. Note that the light-emitting element 100 is the same in configuration as the light-emitting element 10 except that the light-emitting element 100 does not include the IL 5.

Described first in detail are problems when no IL 5 is provided, with reference to FIG. 3.

The ETL 4 is required to match in electron level to the EML 3, and additionally required to be transparent to emitted light. An electron-transporting material that simultaneously satisfies such electric and optical properties includes a metal oxide, a II-VI semiconductor compound, a III-V semiconductor compound, and a IV-IV semiconductor compound as described above. Typically, such materials are formed in ionic bonding. Hence, as illustrated in FIG. 3, the Fermi level of the ETL 4 is a deep surface level close to a center of the bandgap. Note that, because the ETL 4 is of the n-type, the Fermi level of the ETL 4 is positioned shallower than one-half of the bandgap.

Note that, of the IV-IV semiconductor compound, an element semiconductor is formed in a covalent bond such as, for example, a Si—Si bond, a Ge—Ge bond, and a C—C bond. If the IV-IV semiconductor compound is formed of different elements as shown in the exemplary semiconductors, the elements have different closed-shell orbits, and shielding of inner nuclei acts strongly in the order of C, Si and Ge. As a result, iconicity occurs in the bond.

If no defect is found on the surface of the ETL 4, the band bends so that the original work function W of the cathode 6 and the Fermi level of the ETL 4 become equal to each other on a joint interface between the cathode 6 and the ETL 4. Hence, the electron injection barrier Ee is formed to be equal to an energy difference between a conduction band minimum of the ETL 4 and the original work function W of the cathode 6. Note that if the cathode 6 is metal, the work function W is equal to a difference between a vacuum level and an original Fermi level Ef of the cathode 6 when the temperature is the absolute zero (T=0K). In other words, if the cathode 6 is metal, the work function W of the cathode 6 is equal to the Fermi level Ef of the cathode 6.

However, the ETL 4 cannot be completely crystalized no matter what deposition technique is used. Even if the ETL 4 is amorphous, dangling bonds on the surface of the ETL 4 cannot be eliminated. Moreover, for example, the ETL 4 of a QLED is deposited by application of nanoparticles or sputtering.

If the ETL 4 is deposited by application of nanoparticles, the rate of the surface area of the ETL 4 relatively increases thanks to the size effect. The nanoparticles are significantly influenced by the surface area with respect to the volume, and the reactivity of atoms exposed to the surface is significantly larger in nanoparticles than in a bulk. Hence, a surface level, which is difficult to form on a bulk crystal, is easily formed. As a result, as illustrated in FIG. 3, because of a lattice defect and a deviation from stoichiometry, for example, a great deep-level defect (a surface level) deeper than the Fermi level of the ETL 4 is formed on the surface of the ETL 4.

Moreover, in a step of depositing the ETL 4 by sputtering, the ETL 4 is exposed to an impact (ion bombardment) of such a heavy element as ionized argon (Ar). Hence, when the ETL 4 is formed also by sputtering, as illustrated in FIG. 3, a deep-level defect (a surface level) is formed on the surface of the ETL 4. Here, the deep-level defect is deeper than the Fermi level of the ETL 4, and is not formed under a normal condition. That is, in a QLED, the ETL 4 necessarily has a surface level regardless of the film condition.

When the cathode 6 comes in contact with a layer having a deep surface level, charges move between the surface level and the cathode 6, and the Fermi level of the cathode 6 is caught in the surface level (i.e. the Fermi level is pinned to the surface level). Hence, as described above, when the great deep-level defect is formed on the surface of the ETL 4, the Fermi level of the cathode 6 is pinned to the deep-level defect. Thus, the Fermi level of the cathode 6 becomes deep.

As described before, a Fermi level of metal is equal to a work function. Hence, as illustrated in FIG. 3, if no IL 5 is provided, the work function of the cathode 6 does not depend on the original work function W of the cathode 6, and is pinned to the deep-level defect deeper than the Fermi level of the ETL 4. In other words, the work function of the cathode 6 is pinned between substantially the center of the bandgap of the ETL 4 and a position deeper than one-half of the bandgap of the ETL 4. As a result, the work function of the cathode 6 effectively becomes a work function W′, which is significantly larger than the original work function W of the cathode 6.

Hence, in the light-emitting element 100 without the IL 5, the electron injection barrier Ee′ is formed. The electron injection barrier Ee′ is equal to an energy difference between the conduction band minimum of the ETL 4 and the work function W′ of the cathode 6. The electron injection barrier Ee′ is equivalent to an energy difference of substantially half to more than half of the bandgap of the ETL 4. Hence, in the light-emitting element 100 without the IL 5, injection of the electrons is blocked by the electron injection barrier Ee′ that is significantly higher than expected from the properties of the materials of the cathode 6 and the ETL 4. As a result, the drive voltage of the light-emitting element 100 rises, and the efficiency in injection of the electrons decreases.

As described above, the energy level of the EML 3; namely, a light-emitting layer, is determined by a material to be used for the EML 3. The electron affinity is equal to the level of the conduction band minimum. The EML3 included in the light-emitting element 100 in FIG. 3 and formed of quantum dots has an electron affinity of 3.2 eV, which is significantly low. Note that ionization potential is equal to the level of the valence band maximum. The EML 3 included in the light-emitting element 100 in FIG. 3 has an ionization potential of 5.3 eV. Moreover, as illustrated in FIG. 3, for example, the HTL 2 made of NiO has an electron affinity of 2.1 eV and an ionization potential of 5.6 eV. Furthermore, as illustrated in FIG. 3, for example, the ETL 4 made of ZnO has an electron affinity of 3.8 eV and an ionization potential of 7.0 eV.

If the work function W of the cathode 6 is sufficiently shallow to be close to the electron affinity of the ETL 4, the electron injection barrier between the cathode 6 and the ETL 4 is low. However, in the light-emitting element 100 without the IL 5 described above, the electron injection barrier Ee′ to be formed is significantly higher than expected from the properties of the above materials.

Hence, in order to keep the cathode 6 from being pinned to the ETL 4, as illustrated in FIG. 1, this embodiment provides the IL 5 in contact with, and between, the ETL 4 and the cathode 6. The IL 5 has a relative permittivity of 2 or higher and 50 or lower. The IL 5 reduces the move of high-density unpaired electrons, which are derived from the defect on the surface of the ETL 4, to the cathode 6. Hence, as illustrated in FIG. 2, the IL 5 keeps the work function W of the cathode 6 from being pinned to the great deep-level defect on the surface of the ETL 4. Such a feature will be described in detail below.

The energy band structure of the IL 5 is basically the same as that of a semiconductor layer. However, the bandgap of the IL 5; namely, an insulator layer, is significantly wide as described above. Unlike the semiconductor layer, the electrons are not excited from the valence band to the conduction band by thermal energy no higher than a room temperature. Moreover, the mobility of the electrons in the IL 5 is significantly lower than; that is, 10⁻⁶ to 10⁻⁸ times as low as, the mobility of the electrons in the semiconductor layer. Hence, the IL 5 is significantly low in capability of transporting charges. The IL 5 does not allow the charges to move between the deep-level defect (the surface level) of the ETL 4 and the cathode 6.

The IL 5 generates an electric dipole, depending on a relative permittivity of the IL 5. Note that the relative permittivity is defined as follows: “relative permittivity=permittivity/vacuum permittivity”. If the electric dipole is high in density, the work function of the cathode is pinned to the IL 5. Hence, it is not preferable for the IL 5 to have a high relative permittivity. Typically, the permittivity is proportional to the density of the electric dipole. The inventors of the present invention have conducted a thorough study and found out that, in order to keep the cathode 6 from being pinned to the IL 5, the IL 5 has a relative permittivity of preferably 50 or lower, and more preferably, 20 or lower.

Note that when the relative permittivity of the IL 5 is 50, the density of the electric dipole to be excited to the insulator is 5×10²² cm⁻³, and the density of the electric dipole per area of the insulator is 1.4×10¹⁵ cm⁻². Moreover, when the relative permittivity of the IL 5 is 20, the density of the electric dipole to be excited to the insulator is 1.5×10²⁵ cm⁻³, and the density of the electric dipole per area of the insulator is 6×10¹⁶ cm⁻².

The inventors of the present invention used TiO₂ as the insulator because TiO₂ was able to significantly change the relative permittivity (k)(specifically k=10 to 190 as described before), depending on the condition of oxidization. Hence, the inventors prepared a plurality of the light-emitting elements 10 each including an IL 5 having a different relative permittivity. Then, the inventors conducted an experiment to obtain voltage-current characteristics of these light-emitting elements 10. Note that, in the experiment, ultraviolet light to visible light were blocked to eliminate influence of photovoltage by TiO₂. As an example, in the above experiment, the cathode 6 was made of Al, the ETL 4 was made of ZnO, and the anode 1 was made of ITO. Moreover, the HTL 2 was provided. The HTL 2 was made of the TFB described above. Furthermore, the EML 3 was made of core/shell quantum dots emitting red light. Note that the cores were made of cadmium selenide (CdSe), and the shells were made of zinc sulfide (ZnS).

As a result, a voltage starting to energize the light-emitting elements fell when the relative permittivity was 50 or lower, and rose when the relative permittivity was higher than 50. Moreover, the voltage starting to energize the light-emitting elements significantly rose when the relative permittivity exceeded 50. The “electron injection barrier between the cathode 6 and the IL 5” varies for each of the light-emitting elements. The voltage starting to energize the light-emitting elements is assumed to be influenced by the “electron injection barrier between the cathode 6 and the IL 5” that varies for each of the light-emitting elements. Moreover, the voltage was lower when the relative permittivity was 20 or lower than when relative permittivity was up to 50. When the relative permittivity exceeds 50, the work function of the cathode 6 is assumed to be pinned to the IL 5 because of an increase in the density of the electric dipole. Note that, as an example, used in the experiment were quantum dots emitting red light as described above. However, the above advantageous effects are apparent in quantum dots and cadmium (Cd)-free quantum dots emitting blue light. Here, in such quantum dots, the level of the conduction band minimum is shallow.

Moreover, if the relative permittivity is 2 or higher, the IL 5 can have a bandgap of 5 eV or higher, making it possible to ensure the insulating properties of the IL 5.

As can be seen, in this embodiment, the IL 5 whose relative permittivity is 2 or higher and 50 or lower is provided in contact with, and between, the ETL 4 and the cathode 6. Such a feature makes it possible to ensure insulating properties of the IL 5, reduce transportation of charges between the cathode 6 and the surface level (the deep-level defect) of the ETL 4, and keep the Fermi level of the cathode 6 from being pinned to the deep surface level of the ETL 4. Hence, this embodiment can keep the work function W of the cathode 6 from being pinned to the deep surface level of the ETL 4. Thus, this embodiment eliminates influence of the surface level of the ETL 4 on the Fermi level of the cathode 6, making it possible to join the cathode 6 and the ETL 4 together through the IL 5, using the original work function W for the cathode 6. Consequently, in this embodiment, the electron injection barrier between the cathode 6 and the ETL 4 can be reduced from the electron injection barrier Ee′ to the original electron injection barrier Ee formed by a combination of the materials of the cathode 6 and the ETL 4. Such a feature contributes to more efficient injection of the electrons than a conventional technique. Note that, as described above, the above advantageous effects are apparent in quantum dots and cadmium (Cd)-free quantum dots emitting blue light. Here, in such quantum dots, the level of the conduction band minimum is shallow.

### Second Embodiment

This embodiment describes a difference from the first embodiment. Note that, as a matter of convenience, like reference signs denote functionally identical components between this embodiment and the first embodiment. Such components will not be elaborated upon here.

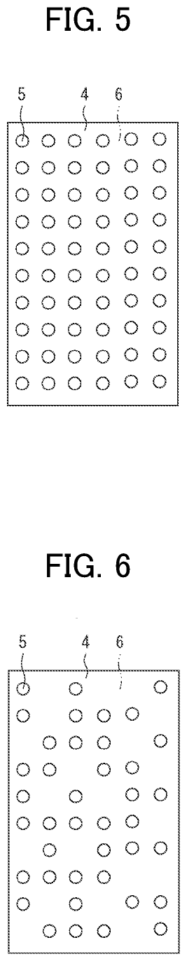

FIG. 4 is a cross-sectional view of an exemplary schematic configuration of the light-emitting device 10 according to this embodiment when the light-emitting element 10 is cut in the normal direction. FIG. 5 is a perspective view of a schematic configuration of an essential part in the light-emitting device 10 according to this embodiment. More specifically, FIG. 5 is a perspective view of the IL 5 and the ETL 4 in the light-emitting device 10 according to this embodiment, when the IL 5 and the ETL 4 are observed from above the light-emitting element 10.

The light-emitting element 10 according to this embodiment is the same as the light-emitting element 10 according to the first embodiment except that, as illustrated in FIGS. 4 and 5, the IL 5 provided on an interface between the ETL 4 and the cathode 6 is not shaped into a continuous film. Instead, the IL 5 includes a plurality of ILs 5 shaped into islands and spaced apart from one another. Hence, the ILs 5 shaped into islands and spaced apart from one another are the same in thickness (in height in the stacking direction of the ILs 5 shaped into islands) as the IL 5 in the first embodiment.

Note that FIG. 5 shows an example of the case where the ILs 5 shaped into islands are formed over the entire light-emitting region of the light-emitting element 10 (more specifically, over the entire top face of the ETL 4 in the example of FIG. 5), and distributed uniformly in plan view.

Note that the light-emitting region of the light-emitting element 10 is a region to emit light in the light-emitting element 10. For example, if an edge cover (not-shown) is provided between the anode 1 and the cathode 6 to cover an end of the anode 1, the light-emitting region of the light-emitting element 10 is an opening of the edge cover to expose the inside of the anode 1.

In forming the ILs 5 by, for example, sputtering, vapor deposition, or application, the ILs 5 are deposited using a mask provided with a plurality of openings. Hence, the ILs 5 can be shaped into islands in a desired pattern. As a matter of course, after deposited by, for example, sputtering, vapor deposition, or application, the ILs 5 may be patterned by photolithography to be shaped into islands in a desired pattern.

As illustrated in FIGS. 4 and 5, the ETL 4 is positioned between the ILs 5 shaped into islands in plan view. As illustrated in FIG. 4, the cathode 6 is provided in contact with the ILs 5 shaped into islands, and with the ETL 4 positioned between the ILs 5 shaped into islands.

As described in the first embodiment, if the IL5 is a continuous film, the electron injection barrier on the entire junction plane between the ETL 4 and the cathode 6 decreases from Ee′ to Ee. Such a feature makes it possible to inject the electrons from the cathode 6 into the ETL 4 through the IL 5 across a wide area.

Meanwhile, in this embodiment, the ILs 5 are shaped into islands. Such a feature makes it possible to reduce the electron injection barrier at the ILs 5 from Ee′ to Ee. Moreover, compared with the case where the IL 5 is a continuous film, in this embodiment, high electric fields concentrate on the ILs 5 such that electrons accelerated with the reduced electron injection barrier concentrate. Such a feature further improves the efficiency in injection of the electrons.

As can be seen, if the ILs 5 allows the Fermi level of even a portion of the cathode 6 to avoid being pinned to the surface level of the ETL 4, the electrons can be selectively injected from a region of the low injection barrier. As can be seen, if the ILs 5 are provided even partially between the ETL 4 and the cathode 6, the Fermi level of the cathode 6 can be kept from being pinned to the surface level of the ETL 4 throughout the cathode 6. Such a feature contributes to more efficient injection of the electrons than a conventional technique. Hence, this embodiment can also achieve the same advantageous effects as the first embodiment does. Consequently, the ILs 5 do not have to be a continuous film.

Note that a typically used material of the ETL is high in resistance and approximately as thin as several tens of nanometers. Hence, in the ETL 4, the current spread is small in the horizontal direction (in the in-plane direction), and the current tends to run directly downwards. Because the ILs 5 are provided between the cathode 6 and the ETL 4, the efficiency in injection of the electrons improves at contacts between the ILs 5 and the cathode 6. However, as described above, the current is likely to run directly downwards of the contacts between the ILs 5 and the cathode 6, and is less likely to spread around the contacts. Thus, the light-emission pattern might not be necessarily uniform when the light-emitting element 10 is observed in a position facing the light-emitting region. Hence, the contacts are distributed uniformly in the light-emitting region so that the light-emission pattern can also be made uniform. However, even if the connections are not continuous, the contacts are distributed in high density so that the light-emission pattern can be made more uniform.

### Third Embodiment

This embodiment describes a difference from the first and second embodiments. Note that, as a matter of convenience, like reference signs denote functionally identical components between this embodiment and the first and second embodiments. Such components will not be elaborated upon here.

FIG. 6 is a perspective view of a schematic configuration of an essential part in the light-emitting device 10 according to this embodiment. More specifically, FIG. 6 is a perspective view of the IL 5 and the ETL 4 in the light-emitting device 10 according to this embodiment, when the IL 5 and the ETL 4 are observed from above the light-emitting element 10.

The light-emitting element 10 according to this embodiment is the same as the light-emitting elements 10 according to the first and second embodiments except that, as illustrated in FIG. 6, a plurality of the ILs 5 shaped into islands are formed over the entire light-emitting region of the light-emitting element 10 (more specifically, over the entire top face of the ETL 4 in the example of FIG. 6), and distributed non-uniformly (irregularly) in plan view.

In this embodiment, in forming the ILs 5 by, for example, sputtering, vapor deposition, or application, the ILs 5 are deposited using a mask provided with a plurality of openings. Hence, the ILs 5 can be shaped into islands in a desired pattern. As a matter of course, after deposited by, for example, sputtering, vapor deposition, or application, the ILs 5 may be patterned by photolithography to be shaped into islands in a desired pattern

As can be seen in the second embodiment, if the ILs 5 can keep the Fermi level of even a portion of the cathode 6 from being pinned, the electrons are selectively injected from a region of the low injection barrier. As a result, the efficiency in injection of the electrons can improve further in this embodiment than in a conventional technique.

Hence, the ILs 5 may be distributed non-uniformly in plan view. This embodiment can achieve the same advantageous effects as the first and second embodiments do.

### Fourth Embodiment

This embodiment describes a difference from the first to third embodiments. Note that, as a matter of convenience, like reference signs denote functionally identical components between this embodiment and the first to third embodiments. Such components will not be elaborated upon here.

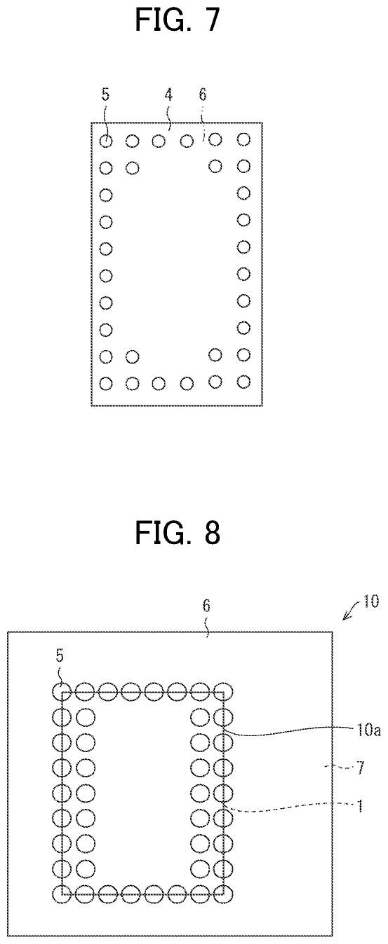

FIG. 7 is a perspective view of a schematic configuration of an essential part in the light-emitting device 10 according to this embodiment. More specifically, FIG. 7 is a perspective view of the IL 5 and the ETL 4 in the light-emitting device 10 according to this embodiment, when the IL 5 and the ETL 4 are observed from above the light-emitting element 10.

The light-emitting element 10 according to this embodiment is the same as the light-emitting elements 10 according to the first to third embodiments except that, as illustrated in FIG. 7, the ILs 5 shaped into islands are formed in a light-emission region of the light-emitting element (more specifically, on the top face of the ETL 4 in the example of FIG. 5), and distributed non-uniformly (irregularly) in plan view, so that the density of which the ILs 5 are arranged is higher in an outer periphery than in a center of the light-emission region.

Note that the “density of which the ILs 5 are arranged” indicates the density in an area where the ILs 5 shaped into islands are in contact with the cathode 6 with respect to an area of the light-emission region of the light-emitting element 10.

In this embodiment, in forming the ILs 5 by, for example, sputtering, vapor deposition, or application, the ILs 5 are deposited using a mask provided with a plurality of openings. Hence, the ILs 5 can be shaped into islands in a desired pattern. As a matter of course, after deposited by, for example, sputtering, vapor deposition, or application, the ILs 5 may be patterned by photolithography to be shaped into islands in a desired pattern.

In this case, too, the efficiency in injection of the electrons can improve further in this embodiment than in a conventional technique because of the same reasons as those described in the second and third embodiments. Hence, this embodiment can also achieve the same advantageous effects as the first to third embodiments do. Moreover, this embodiment can eliminate influence of the surface level of the ETL 4 on the Fermi level of the cathode 6 on the outer periphery, of the light-emission region of the light-emitting element 10, on which an external electric field is easily concentrated. As a result, on the outer periphery on which the external electric field is easily concentrated, the Fermi level of the cathode 6 can be kept from being pinned and the efficiency in injection of the electrons can be improved.

Note that, as illustrated in FIG. 7, the center of the light-emission region does not have to be provided with the ILs 5.

### Fifth Embodiment

This embodiment describes a difference from the first to fourth embodiments. Note that, as a matter of convenience, like reference signs denote functionally identical components between this embodiment and the first to fourth embodiments. Such components will not be elaborated upon here.

FIG. 8 is a perspective view of a schematic configuration of an essential part in the light-emitting device 10 according to this embodiment. More specifically, FIG. 8 is a perspective view of the IL 5 in the light-emitting device 10 according to this embodiment, when the IL 5 is observed from above the light-emitting element 10.

The light-emitting element 10 according to this embodiment includes an edge cover provided between the anode 1 and the cathode 6 to cover an end of the anode 1. The edge cover 7 has an opening to expose the inside of the anode 1, and the opening is a light-emission region 10a of the light-emitting element 10 according to this embodiment. The light-emitting element 10 according to this embodiment is the same as the light-emitting element 10 according to the fourth embodiment except that the light-emission region 10a of the light-emitting element 10 has an end overlapping the ILs 5.

In this embodiment, in forming the ILs 5 by, for example, sputtering, vapor deposition, or application, the ILs 5 are deposited using a mask provided with a plurality of openings. Hence, the ILs 5 can be shaped into islands in a desired pattern. As a matter of course, after deposited by, for example, sputtering, vapor deposition, or application, the ILs 5 may be patterned by photolithography to be shaped into islands in a desired pattern.

This embodiment can also achieve the same advantageous effects as the fourth embodiment does because of the same reasons described in the fourth embodiment.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### REFERENCE SIGNS LIST

1 Anode
3 EML (Light-Emitting Layer)
4 ETL (Layer Capable of Transporting Electrons)
5 IL (Insulating Layer)
6 Cathode
10 Light-Emitting Element
10a Light-Emitting Region

1. A light-emitting element, comprising:
an anode, a light-emitting layer, a layer capable of transporting electrons, and a cathode, all of which are provided in a stated order; and
an insulator layer provided in contact with, and at least partially between, the layer capable of transporting the electrons and the cathode, the insulator layer having a relative permittivity of 2 or higher and 50 or lower, wherein
the insulator layer includes a plurality of insulator layers shaped into islands and spaced apart from one another, and
the insulator layers are distributed non-uniformly in plan view.

2. The light-emitting element according to claim 1, wherein
the insulator layer has a bandgap of 5 eV or higher and 10 eV or lower.

3. The light-emitting element according to claim 2, wherein
the insulator layer has a bandgap of 8 eV or higher.

4. The light-emitting element according to claim 1, wherein
the insulator layer has a relative permittivity of 20 or lower.

5. The light-emitting element according to claim 1, wherein
the insulator layer has a thickness of 0.1 to 2 nm.

6-9. (canceled)

10. The light-emitting element according to claim 1, wherein
a density of which the insulator layers are arranged is higher in an outer periphery than in a center of a light-emission region of the light-emitting element.

11. The light-emitting element according to claim 10, wherein
the center of the light-emission region is not provided with the insulator layer.

12. The light-emitting element according to claim 10, wherein
the light-emission region of the light-emitting element has an end overlapping the insulator layers.

13. The light-emitting element according to claim 1, wherein
the layer capable of transporting the electrons is positioned between the insulator layers in plan view, and provided in contact with the cathode.

14. A light-emitting element, comprising:
an anode, a light-emitting layer, a layer capable of transporting electrons, and a cathode, all of which are provided in a stated order; and
an insulator layer provided in contact with, and at least partially between, the layer capable of transporting the electrons and the cathode, the insulator layer having a relative permittivity of 2 or higher and 50 or lower, wherein
the insulator layer includes a plurality of insulator layers shaped into islands and spaced apart from one another, and
the layer capable of transporting the electrons is positioned between the insulator layers in plan view, and provided in contact with the cathode.

15. The light-emitting element according to claim 14, wherein
the insulator layers are distributed uniformly in plan view.
